(19) United States
(12) Patent Application Publication
(10) Pub. No.: US 2004/0003156 A1
(43) Pub. Date: Jan. 1, 2004

(54) Synchronizing circuit cards of electronic modules

(75) Inventors: Yochai Parchak, Raanana (IL); Amir Sharon, Ramat Hasharon (IL); Atias Meiron, Shaar-Afraim (IL); Avi Reuveni, Gevat-Shemoal (IL)

Correspondence Address: Fogg Slifer Polglaze Leffert & Jay, P.A., P.O. Box 581009, Minneapolis, MN, 55458-1009, US

(73) Assignee: ADC Telecommunications Israel Ltd.

(21) Appl. No.: 10/187,185

(22) Filed: Jul. 1, 2002

(51) Int. Cl. H05K 7/10; G06F 13/00

(52) U.S. Cl. 710/301

(57) ABSTRACT

An electronic module that has a card cage having slots for first and second common cards located at different ends of the card cage and a plurality of slots between the slots for the first and second common cards for receiving a plurality electronic circuit cards each providing a clock source within the card cage. The electronic module has a bus that connects the plurality of slots for receiving the plurality electronic circuit cards with the slots for the first and second common cards such that the bus provides a substantially equal distance to the slots for the first and second common cards from any of the plurality of slots for receiving the plurality electronic circuit cards.

### TECHNICAL FIELD

The present invention relates generally to the field of electronic modules and, in particular, to synchronizing circuit cards of electronic modules.

### BACKGROUND

Many electronic modules, such as electronic modules deployed at central offices and remote locations of telecommunications systems, include a number of electronic circuit cards, such as line cards, e.g., digital subscriber line (DSL) cards, common telephony module (CTM) cards, or the like. These line cards are usually electrically connected to a backplane of the electronic module. Some electronic modules also include a common (or management) electronic circuit card electrically connected to the backplane for managing operation of the line cards.

Some electronic modules employ two common cards electrically connected to backplanes of the electronic modules: a primary common card and a backup common card that replaces the primary common card if the primary common card fails. In order for the backup common card to properly manage operation of the line cards when taking over for the primary common card, operation of the primary and backup common cards must be synchronized. This is usually accomplished by receiving a common clock signal, e.g., a clock having substantially the same frequency and phase, at each of the primary and backup common cards from each of the line cards via a trace disposed within or on the backplane that interconnects the primary and backup common cards and the line cards. However, in many applications, the distance traveled by the clock signal in going from a line card to the primary common card is different from the distance traveled by the clock signal in going from the line card to the backup common card. This causes the clock signals arriving at the primary and backup common cards to be out of phase, making it difficult to synchronize operation of the primary and backup common cards.

For the reasons stated above, and for other reasons stated below that will become apparent to those skilled in the art upon reading and understanding the present specification, there is a need in the art alternatives for synchronizing operation of circuit cards of electronic modules.

### SUMMARY

The above-mentioned problems with synchronizing operation of circuit cards of electronic modules and other problems are addressed by embodiments of the present invention and will be understood by reading and studying the following specification.

In one embodiment, an electronic module is provided. The electronic module has a card cage having slots for first and second common cards located at different ends of the card cage and a plurality of slots between the slots for the first and second common cards for receiving a plurality electronic circuit cards each providing a clock source within the card cage. The electronic module has a bus that connects the plurality of slots for receiving the plurality electronic circuit cards with the slots for the first and second common cards such that the bus provides a substantially equal distance to the slots for the first and second common cards from any of the plurality of slots for receiving the plurality electronic circuit cards.

In another embodiment, an electronic module having a backplane is provided. First and second circuit cards are electrically connected to the backplane. At least one additional circuit card is electrically connected to the backplane and located between the first and second circuit cards. A first trace disposed within or on the backplane electrically interconnects the first, second, and at least one additional circuit cards. At least one looped trace disposed within or on the backplane electrically connects the at least one additional circuit card to the first circuit card. A first distance around the at least one looped trace from the at least one additional circuit card to the first circuit card is substantially equal to a second distance along the first trace from the at least one additional circuit card to the second circuit card, whereby first and second clock signals respectively traveling over the first and second distances have substantially the same phase upon arrival at the first and second circuit cards.

In another embodiment, an electronic module having first and second circuit cards and a multiplexer having first and second ports is provided. The first port is connected to the first and second circuit cards and is adapted to receive a first clock signal from a selected one of the first or second circuit cards. The second port is connected to the first circuit card and is adapted to receive a second clock signal from the first circuit card when selected. Moreover, the multiplexer includes a control port adapted to receive control signals and an output port. A controller having an input coupled to the second port and an output connected to the control port of the multiplexer is also included. The controller causes the multiplexer to pass the second clock signal to the output port when present and the first clock signal when the second clock signal is not present.

Further embodiments of the invention include methods and apparatus of varying scope.

### BRIEF DESCRIPTION OF THE DRAWINGS

FIG. 1 illustrates an electronic module according to an embodiment of the present invention.

FIG. 2 is an enlarged view of region 200 of FIG. 1.

FIG. 3 illustrates an electronic circuit according to another embodiment of the present invention.

FIG. 4 illustrates a card cage of the electronic module of FIG. 1 according to another embodiment of the present invention.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense.

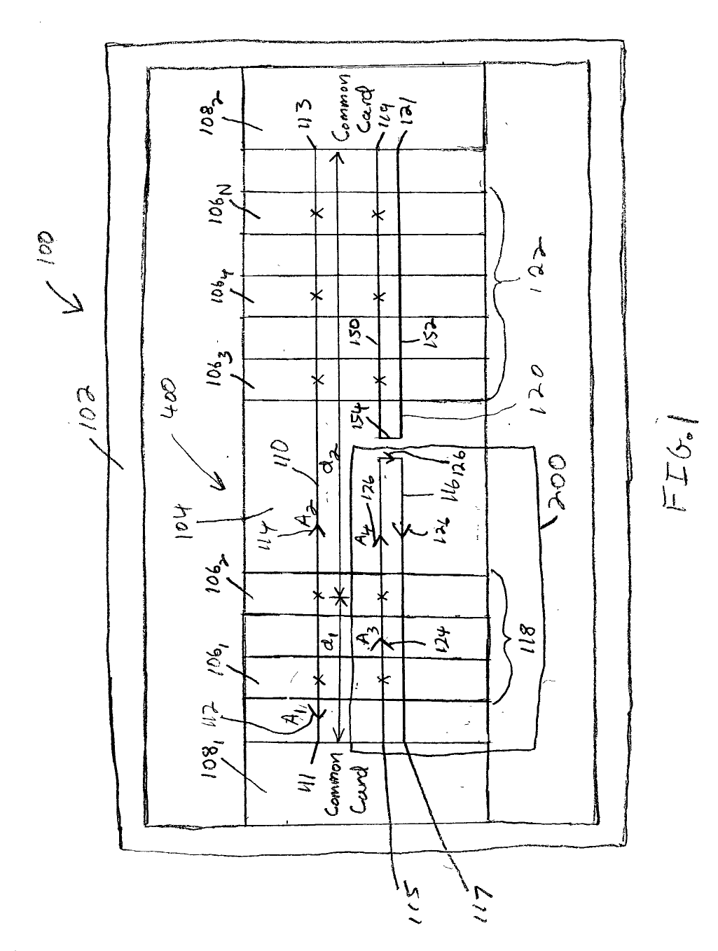

FIG. 1 illustrates an electronic module 100, such as a telecommunications module, according to an embodiment of the present invention. In some embodiments, electronic module 100 is deployed in a central office, remote unit, or the like of a telecommunications system. In one embodiment, electronic module 100 is a digital subscriber line (DSL)/voice gateway, such as the MG-1 Multimedia Gateway available from ADC Telecommunications, Eden Prairie, Minn.

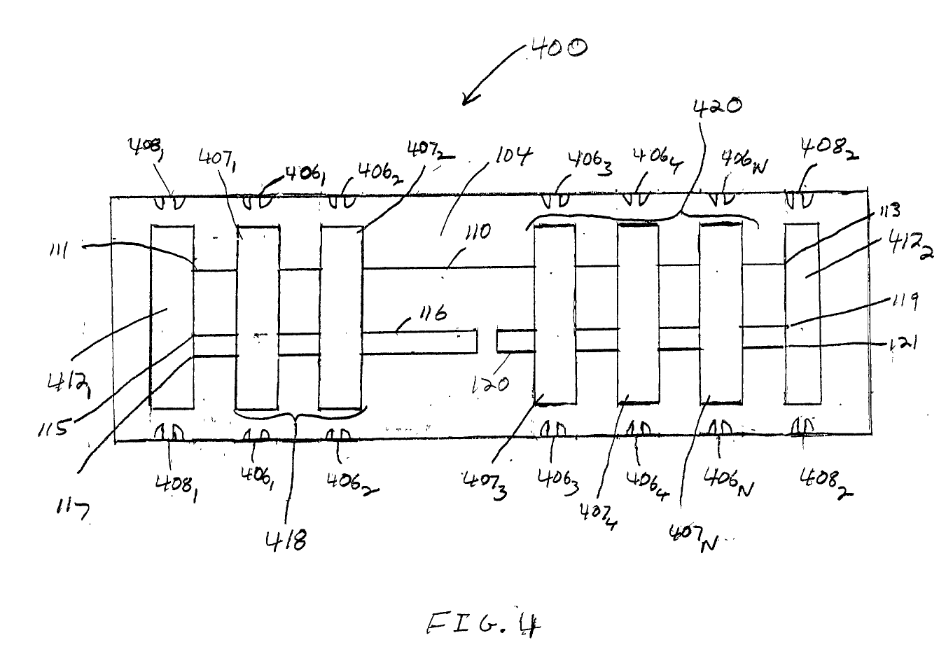

Electronic module 100 includes a housing 102. A backplane 104 is disposed within housing 102. Electronic circuit cards 106₁ to 106_{N} are removably located within housing 102 and are electrically connectable to backplane 104. In one embodiment, electronic module 100 includes a card cage 400 (e.g., as illustrated in FIG. 4) disposed in housing 102. Electronic circuit cards 106₁ to 106_{N} are respectively removably located within slots 406₁ to 406_{N} of card cage 400 and respectively mate with connectors 407₁ to 407_{N} electrically connected to backplane 104. In various embodiments, electronic circuit cards 106₁ and 106_{N} are removable line cards, such as for providing telephony service, e.g., common telephony module (CTM) cards, for providing DSL service, e.g., high-bit-rate DSL (HDSL), asymmetric DSL (ADSL), very high-bit-rate DSL (VDSL), single-pair (or G.symmetric) HDSL (G.shdsl), and others.

Common (or management) electronic circuit cards 108₁ and 108₂ are removably located within housing 102 respectively on either side of electronic circuit cards 106₁ to 106_{N} and are electrically connectable to backplane 104. In one embodiment, common electronic circuit cards 108₁ and 108₂ are respectively located in slots 408₁ and 408₂ of card cage 400 and respectively mate with connectors 412₁ and 412₂ electrically connected to backplane 104. In another embodiment, one of common electronic circuit cards 108, e.g., common electronic circuit card 108₁, is a primary common electronic circuit card and the other, e.g., common electronic circuit card 108₂, is a redundant (or backup) common electronic circuit card. During operation, the primary common electronic circuit card manages operation of electronic circuit cards 106₁ to 106_{N}. If the primary common electronic circuit card fails, it is turned off, and the backup common electronic circuit card replaces the primary common electronic circuit card, taking over management of operation of electronic circuit cards 106₁ to 106_{N}. In another embodiment, common electronic circuit cards 108 include circuitry, such as functional circuitry, control circuitry for managing operation of electronic circuit cards 106₁ to 106_{N}, or the like.

In order for common electronic circuit card 108₂ to properly manage operation of electronic circuit cards 106₁ to 106_{N} when taking over for common electronic circuit card 108₁ if common electronic circuit card 108₁ fails, operation of common electronic circuit cards 108₁ and 108₂ must be synchronized. This is accomplished by receiving clock signals having substantially the same frequency and phase at both of common electronic circuit cards 108, and 1082 from electronic circuit cards 106₁ to 106_{N}.

A trace 110 disposed within or on backplane 104 electrically interconnects electronic circuit cards 106₁ to 106_{N} and common electronic circuit cards 108₁ and 1082 via corresponding connectors 407₁ to 407_{N} and corresponding connectors 412₁ and 412₂. Ends 111 and 113 of trace 110 are respectively connected to common electronic circuit cards 108₁ and 108₂ via respective connectors 412₁ and 412₂. Trace 110 serves as a bus for conveying a clock signal transmitted from a selected one of electronic circuit cards 106₁ to 106_{N} to common electronic circuit cards 108₁ and 108₂. In one embodiment, any one of electronic circuit cards 106₁ to 106_{N} is used to generate a clock signal for common electronic circuit cards 108₁ to 108₂. In another embodiment, a clock signal is conveyed from one of common electronic circuit cards 108 to the other via trace 110.

In one example, as illustrated in FIG. 1, trace 110 conveys the clock signal as clock signals A₁ and A₂ in directions of arrowheads 112 and 114 from electronic circuit card 1062 to common electronic circuit cards 108₁ and 108₂, respectively. In going from electronic circuit card 106₂ to common electronic circuit card 108₁, clock signal A₁ travels a distance d₁ in the direction of arrowhead 112. In going from electronic circuit card 1062 to common electronic circuit card 1082, clock signal A₂ travels a distance d₂ in the direction of arrowhead 114 that is different from distance dl. It will be appreciated by those skilled in the art that because clock signals A₁ and A₂ travel over two different distances in going from electronic circuit card 1062 to common electronic circuit cards 1081 and 1082, clock signals A₁ and A₂ will be out of phase with each other upon arriving at common electronic circuit cards 108₁ and 108₂. Consequently, common electronic circuit cards 108₁ and 108₂ will not be properly synchronized.

A looped trace 116 disposed within or on backplane 104 electrically interconnects a sequence 118 of electronic circuit cards 106₁ to 106_{N}, e.g., electronic circuit cards 106₁ to 106₂, and common electronic circuit card 108₁ via a corresponding sequence 418 of connectors 407 (e.g., 407₁ to 407₂) and corresponding connector 412₁.

Looped trace 116 has ends 115 and 117 each connected to common electronic circuit card 108₁ via connector 412₁. When the selected one of electronic circuit cards 106₁ to 106_{N} is from sequence 118, looped trace 116 conveys the clock signal transmitted from the selected one of electronic circuit cards 106₁ to 106_{N} to common electronic circuit card 108₁.

A looped trace 120 disposed within or on backplane 104 electrically interconnects a sequence 122 of electronic circuit cards 106₁ to 106_{N}, e.g., electronic circuit cards 106₃ to 106_{N}, and common electronic circuit card 108₂ via a corresponding sequence 420 of connectors 407 (e.g., 407₃ to 407_{N}) and corresponding connector 412₂. Looped trace 120 has ends 119 and 121 each connected to common electronic circuit card 108₂ via connector 412₂. When the selected one of electronic circuit cards 106₁ to 106_{N} is from sequence 122, looped trace 120 conveys the clock signal transmitted from the selected one of the electronic circuit cards 106₁ to 106_{N} to common electronic circuit card 108₂.

In one embodiment, looped traces 116 and 120 include first and second parallel segments, such as parallel segments 150 and 152, respectively, of looped trace 120, that extend from one of the common modules 108 toward the center of housing 102. Looped traces 116 and 120 also include a connector segment, such as connector segment 154 of looped trace 120, that connects the first and second segments near the center of housing 102. The lengths of the respective segments are chosen so that the distance from each electronic card 106 along the first segment to the connector segment, along the connector segment to the second segment, and along the second segment to the common card 108 is substantially the same as the distance from the same card to the opposite common card 108 along trace 110.

Looped traces 116 and 120 substantially equalize the distance traveled by a clock signal going from an associated one of electronic circuit cards 106₁ to 106_{N} to one of common electronic circuit cards 108₁ and 108₂ with the distance traveled by a clock signal on trace 110 from the same one of electronic circuit cards 106₁ to 106_{N} to the other of the common electronic circuit cards 108₁ and 108₂. This enables common electronic circuit cards 108₁ and 108₂ to receive clock signals from any of electronic circuit cards 106 that have the same phase.

For example, when trace 110 conveys the clock signal as clock signals A₁ and A₂ from electronic circuit card 106₂ to common electronic circuit cards 108₁ and 108₂, looped trace 116 conveys the clock signal as clock signal A₄ in a direction of arrowhead 126 from electronic circuit card 106₂ to common electronic circuit card 108₁. In going from electronic circuit card 106₂ to common electronic circuit card 108₁, clock signal A₄ travels around looped trace 116 in the direction of arrowheads 126. In traveling around looped trace 116, clock signal A₄ travels a distance D equal to the sum of distances d₄, d₅, and d₆. Distance D is substantially equal to the distance d₂ traveled by clock signal A₂ in going electronic circuit card 106₂ to common electronic circuit card 108₂. Therefore, the clock signal A₂ received at common electronic circuit card 108₂ and the clock signal A₄ received at common electronic circuit card 108₁ have substantially the phase.

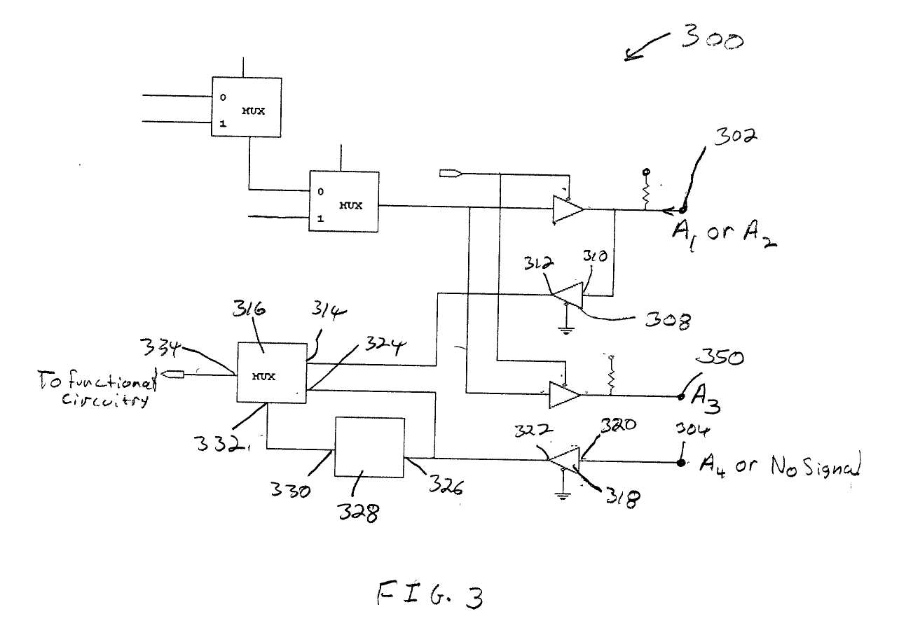

In the above example, common electronic circuit card 108₁ receives clock signals A₁ and A₄, where clock signals A₁ and A₄ are out of phase because they travel over different distances from electronic circuit card 106₂. Moreover, common electronic circuit card 108₂ receives clock signal A₂ that has substantially the same phase as clock signal A₄ because clock signals A₂ and A₄ travel over substantially the same distances from electronic circuit card 106₂. In order to synchronize common electronic circuit cards 108₁ and 108₂, common electronic circuit cards 108₁ and 108₂ need to respectively select clock signals having substantially the same phase, e.g., clock signals A₂ and A₄. In one embodiment, this is accomplished using an electronic circuit 300, as shown in FIG. 3, of each of common electronic circuit cards 108₁ and 108₂. In other embodiments, any appropriate circuit is used to select the in-phase signals at common electronic circuit cards 108₁ to 108₂.

Circuit 300 has a port 302 connected to trace 110 for receiving a clock signal, such as clock signals A₁ or A₂, any one of electronic circuit cards 106₁ to 106_{N} or from the other common card 108 via trace 110. Circuit 300 has an input port 304 connected to one of looped traces 116 or 120 such that input 304 receives clock signals, such as clock signal A₄, that have traveled around the respective one of looped traces 116 or 120. In terms of the above example, the circuit 300 of common electronic circuit card 108₁ receives clock signals A₁ and A₄ respectively at input ports 302 and 304, as shown in FIG. 3. Meanwhile, the circuit 300 of common electronic circuit card 108₂ receives clock signal A₂ at port 302 and no clock signal at input port 304, as shown in FIG. 3.

Circuit 300 includes a buffer 308 having an input port 310 connected to port 302 and an output port 312 connected to an input port 314 of a multiplexer 316. A buffer 318 of circuit 300 has an input port 320 connected to input port 304 and an output port 322 connected to an input port 324 of multiplexer 316 and to an input port 326 of a controller 328. Controller 328 has an output port 330 connected to a control port 332 of multiplexer 316. Multiplexer 316 includes an output port 334 that serves as an output port for circuit 300 that is connected to other electronic circuitry, such as functional circuitry, control circuitry for managing operation of electronic circuit cards 106₁ to 106_{N}, or the like, of the respective one of common electronic circuit cards 108.

Input port 314 of multiplexer 316 is normally open. Therefore, when clock signal A₂ is received at port 302 and no clock signal is received at input port 304, clock signal A₂ passes from port 302 to input port 314 via buffer 308. Multiplexer 316 transmits clock signal A₂ from input port 314 to output port 334 and thus to the other circuitry of common electronic circuit card 108₂, for example. In terms of the above example, this corresponds to common electronic circuit card 108₂ selecting clock signal A₂.

When clock signals A₁ and A₄ are respectively at input ports 302 and 304, controller 328 receives clock signal A₄ at port 326 and sends a control signal to multiplexer 316 that instructs multiplexer 316 to close input port 314 and open input port 324. This allows clock signal A₄ to pass from input 304 to input port 324 via buffer 318. Multiplexer 316 transmits clock signal A₄ from input port 324 to output port 334 and thus to the other circuitry of common electronic circuit card 108₁, for example. In terms of the above example, this corresponds to common electronic circuit card 108₁ selecting clock signal A₄ that has substantially the same phase as clock signal A₂ selected by common electronic circuit card 108₂, thus enabling synchronization of common electronic circuit cards 108₁ and 108₂.

In one embodiment, controller 328 is a logic device. When there is no input at input port 304, controller 328 outputs a logical zero to multiplexer 316 that effectively selects input port 314 to receive the clock signal from input 302, e.g., port 314 remains normally open. When there is a clock signal at input port 304, controller 328 outputs a logical one to multiplexer 316 that effectively selects input port 324 to receive the clock signal from input 304, e.g., input port 314 is closed and input port 324 is opened.

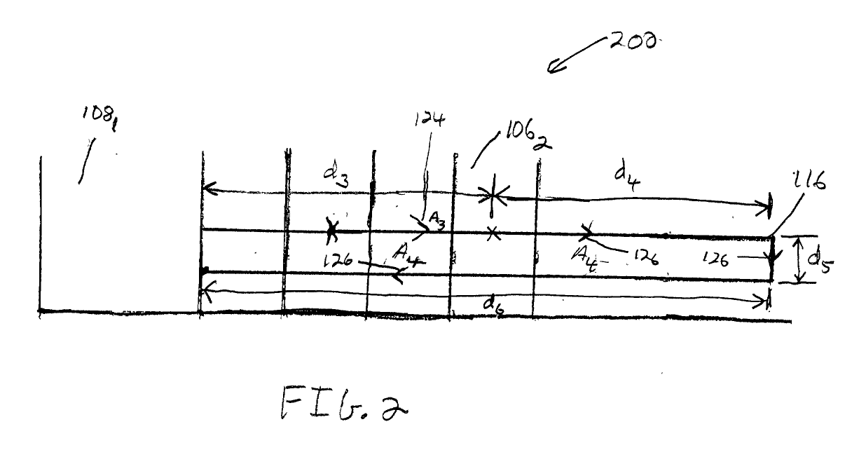

In one embodiment, circuit 300 has an output port 350 connected to one of looped traces 116 or 120 for outputting clock signals to any one of the circuit cards 106 connected to the respective looped traces 116 or 120. For example, circuit 300 outputs a clock signal A₃ at output 350. Clock signal A₃ travels over looped trace 116 in the direction of arrow 124 to electronic circuit card 106₂, as shown in FIGS. 1 and 2. In another embodiment, port 302 is an input/output port. When operating as an output port, port 302 outputs clock signals to any one of electronic circuit cards 106 via trace 110.

### Conclusion

Embodiments of the present invention have been described. The embodiments provide for synchronizing operation of a pair of circuit cards, such as primary and backup common cards, of an electronic module used for managing other cards, such as line cards, of the module. This is accomplished by receiving clock signals at each of the pair of circuit cards having substantially the same phase from the other circuit cards, irrespective of how far the other cards are located from each of the pair of circuit cards.

Although specific embodiments have been illustrated and described in this specification, it will be appreciated by those of ordinary skill in the art that any arrangement that is calculated to achieve the same purpose may be substituted for the specific embodiment shown. This application is intended to cover any adaptations or variations of the present invention. For example, looped traces 116 and 118 may be the same length and connect the same number of electronic circuit cards 106 to the respective common electronic circuit cards 108. Alternatively, looped traces may have different lengths and connect different numbers of electronic circuit cards 106 to the respective common electronic circuit cards 108. It is manifestly intended that this invention be limited only by the following claims and equivalents thereof.

What is claimed is:

1. An electronic module comprising:
a backplane;
first and second circuit cards electrically connected to the backplane;
at least one additional circuit card electrically connected to the backplane and located between the first and second circuit cards;
a first trace disposed within or on the backplane electrically interconnecting the first, second, and at least one additional circuit cards; and
at least one looped trace disposed within or on the backplane electrically connecting the at least one additional circuit card to the first circuit card, wherein a first distance around the at least one looped trace from the at least one additional circuit card to the first circuit card is substantially equal to a second distance along the first trace from the at least one additional circuit card to the second circuit card, whereby first and second clock signals respectively traveling over the first and second distances have substantially the same phase upon arrival at the first and second circuit cards.

2. The electronic module of claim 1, wherein the second circuit card is a backup circuit card for the first circuit card that replaces the first circuit card if the first circuit card fails.

3. An electronic module comprising:
a backplane;
a pair of first circuit cards electrically connected to the backplane;
a second circuit card electrically connected to the backplane and located between the pair of first circuit cards;
a first trace disposed within or on the backplane electrically interconnecting the pair of first circuit cards and the second circuit card, first and second ends of the first trace respectively connected to each of the pair of first circuit cards, wherein during operation of the electronic module, a first clock signal travels a first distance in a first direction through the first trace from the second circuit card to a first of the pair of first circuit cards and a second clock signal travels a second distance in a second direction through the first trace from the second circuit card to a second of the pair of first circuit cards; and
a second trace disposed within or on the backplane having first and second ends connected to the first of the pair of first circuit cards to form a loop, the second trace electrically connecting the second circuit card to the first of the pair of first circuit cards, wherein during operation of the electronic module, a third clock signal travels a third distance through the second trace around the loop from the second circuit card to the first of the pair of first circuit cards, wherein the third distance is substantially equal to the second distance so that the second and third clock signals have substantially the same phase at the second and first of the pair of first circuit cards, respectively.

4. The electronic module of claim 3, wherein the second of the pair of first circuit cards is a backup circuit card for the first of the pair of first circuit cards that replaces the first of the pair of first circuit cards if the first of the pair of first circuit cards fails.

5. The electronic module of claim 3, wherein the first of the pair of first electronic circuit cards comprises an electronic circuit that receives the first clock signal and the third clock signal and selects the third clock signal to be sent to other electronic circuitry of the first of the pair of first electronic circuit cards.

6. An electronic module comprising:
a backplane;
a pair of first electronic circuit cards electrically connected to the backplane;
a plurality of second electronic circuit cards disposed between the pair of first electronic circuit cards and electrically connected to the backplane;
a first trace disposed within or on the backplane electrically interconnecting the pair of first electronic circuit cards and the plurality of second electronic circuit cards, wherein first and second ends of the first trace are respectively connected to each of the pair of first electronic circuit cards, wherein during operation of the electronic module, a first clock signal travels in a first direction within the first trace over a first distance from a selected one of the plurality of second electronic circuit cards to a first of the pair of first electronic circuit cards and a second clock signal travels in a second direction within the first trace over a second distance from the selected one of the plurality of second electronic circuit cards to a second of the pair of first electronic circuit cards;
a second trace disposed within or on the backplane having first and second ends each connected to the first of the pair of first electronic circuit cards to form a first loop, the second trace electrically connecting a first sequence of the plurality of second electronic circuit cards to the first of the pair of first electronic circuit cards, wherein when the selected one of the plurality of second electronic circuit cards is from the first sequence, a third clock signal travels around the first loop within the second trace over a third distance from the selected one of the plurality of second electronic circuit cards to the first of the pair of first electronic circuit cards so that the third distance is substantially equal to the second distance, whereby the second and third clock signals have substantially the same phase respectively at the second and first of the pair of first electronic circuit cards; and
a third trace disposed within or on the backplane having first and second ends each connected to the second of the pair of first electronic circuit cards to form a second loop, the third trace electrically connecting a second sequence of the plurality second electronic circuit cards to the second of the pair of first electronic circuit cards, wherein when the selected one of the plurality of second electronic circuit cards is from the second sequence, a fourth clock signal travels around the second loop within the third trace over a fourth distance from the selected one of the plurality of second electronic circuit cards to the second of the pair of first electronic circuit cards so that the fourth distance is substantially equal to the first distance, whereby the first and fourth clock signals have substantially the same phase respectively at the first and second of the pair of first electronic circuit cards.

7. The electronic module of claim 6, wherein the second of the pair of first electronic circuit cards is a backup electronic circuit card for the first of the pair of first electronic circuit cards that replaces the first of the pair of first electronic circuit cards if the first of the pair of first electronic circuit cards fails.

8. The electronic module of claim 6, wherein the first of the pair of first electronic circuit cards comprises an electronic circuit that receives the first and third clock signals and selects the third clock signal to be sent to other electronic circuitry of the first of the pair of first electronic circuit cards.

9. The electronic module of claim 6, wherein the second of the pair of first electronic circuit cards comprises an electronic circuit that receives the second and fourth clock signals and selects the fourth clock signal to be sent to other electronic circuitry of the second of the pair of first electronic circuit cards.

10. An electronic module comprising:
a backplane;
a pair of first electronic circuit cards electrically connected to the backplane,
a plurality of second electronic circuit cards disposed between the pair of first electronic circuit cards and electrically connected to the backplane;
a first trace disposed within or on the backplane electrically interconnecting the pair of first electronic circuit cards and the plurality of second electronic circuit cards, wherein first and second ends of the first trace are respectively connected to each of the pair of first electronic circuit cards, wherein during operation of the electronic module, a first clock signal travels in a first direction within the first trace over a first distance from a selected one of the plurality of second electronic circuit cards to a first of the pair of first electronic circuit cards and a second clock signal travels in a second direction within the first trace over a second distance from the selected one of the plurality of second electronic circuit cards to a second of the pair of first electronic circuit cards;
a second trace disposed within or on the backplane having first and second ends each connected to the first of the pair of first electronic circuit cards to form a first loop, the second trace electrically connecting a first sequence of the plurality of second electronic circuit cards to the first of the pair of first electronic circuit cards, wherein when the selected one of the plurality of second electronic circuit cards is from the first sequence, a third clock signal travels around the first loop within the second trace over a third distance from the selected one of the plurality of second electronic circuit cards to the first of the pair of first electronic circuit cards so that the third distance is substantially equal to the second distance, whereby the second and third clock signals have substantially the same phase respectively at the second and first of the pair of first electronic circuit cards;
a third trace disposed within or on the backplane having first and second ends each connected to the second of the pair of first electronic circuit cards to form a second loop, the third trace electrically connecting a second sequence of the plurality second electronic circuit cards to the second of the pair of first electronic circuit cards, wherein when the selected one of the plurality of second electronic circuit cards is from the second sequence, a fourth clock signal travels around the second loop within the third trace over a fourth distance from the selected one of the plurality of second electronic circuit cards to the second of the pair of first electronic circuit cards so that the fourth distance is substantially equal to the first distance, whereby the first and fourth clock signals have substantially the same phase respectively at the first and second of the pair of first electronic circuit cards;
wherein when the selected one of the plurality of second electronic circuit cards is from the first sequence, an electronic circuit of the first of the pair of first electronic circuit cards receives the first and third clock signals and an electronic circuit of the second of the pair of first electronic circuit cards receives the second clock signal, the electronic circuit of the first of the pair of first electronic circuit cards selecting and sending the third clock signal to other electronic circuitry of the first of the pair of first electronic circuit cards and the electronic circuit of the second of the pair of first electronic circuit cards sending the second clock signal to other electronic circuitry of the second of the pair of first electronic circuit cards; and
wherein when the selected one of the plurality of second electronic circuit cards is from the second sequence, the electronic circuit of the second of the pair of first electronic circuit cards receives the second and fourth clock signals and the electronic circuit of the first of the pair of first electronic circuit cards receives the first clock signal, the electronic circuit of the second of the pair of first electronic circuit cards selecting and sending the fourth clock signal to the other electronic circuitry of the second of the pair of first electronic circuit cards and the electronic circuit of the first of the pair of first electronic circuit cards sending the first clock signal to the other electronic circuitry of the first of the pair of first electronic circuit cards.

11. An electronic circuit for selecting a clock signal, comprising:
a multiplexer having first and second ports for receiving first and second clock signals, respectively, the multiplexer including a control port adapted to receive control signals and an output port that provides an output of the electronic circuit for outputting the selected clock signal; and
a controller having an input coupled to the second port and an output connected to the control port of the multiplexer;
wherein the controller causes the multiplexer to pass the second clock signal when present and the first clock signal when the second clock signal is not present.

12. The electronic circuit of claim 11, further comprising a first buffer connected to the first port of the multiplexer and a second buffer connected to the second port of the multiplexer and the input of the controller.

13. A common electronic module comprising:
a multiplexer having first and second ports for receiving first and second clock signals, respectively, from a selected one of a plurality of circuit cards disposed within a housing, the multiplexer including a control port adapted to receive control signals and an output port;
a controller having an input coupled to the second port and an output connected to the control port of the multiplexer; and
control circuitry connected to the output port of the multiplexer adapted to manage the plurality of electronic circuit cards;
wherein the controller causes the multiplexer to pass the second clock signal to the control circuitry via the output port when present and the first clock signal when the second clock signal is not present.

14. The electronic circuit of claim 13, further comprising a first buffer connected to the first port of the multiplexer and a second buffer connected to the second port of the multiplexer and the input of the controller.

15. An electronic module comprising:
first and second circuit cards;
a multiplexer having first and second ports, the first port connected to the first and second circuit cards and adapted to receive a first clock signal from a selected one of the first or second circuit cards, the second port connected to the first circuit card and adapted to receive a second clock signal from the first circuit card when selected, the multiplexer including a control port adapted to receive control signals and an output port; and
a controller having an input coupled to the second port and an output connected to the control port of the multiplexer;
wherein the controller causes the multiplexer to pass the second clock signal to the output port when present and the first clock signal when the second clock signal is not present.

16. The electronic module of claim 15, wherein a looped trace disposed within or on a backplane of the electronic module interconnects the first circuit card and the second port.

17. The electronic module of claim 15, wherein a trace disposed within or on a backplane of the electronic module interconnects the first and second circuit cards and the first port.

18. The electronic module of claim 15, wherein the output of the circuit is connected to other circuitry of the electronic module.

19. A backplane comprising:
a pair of first connectors respectively electrically connectable to a pair of common electronic modules;
a plurality of second connectors located between the pair of first connectors, each of the plurality of second connectors respectively electrically connectable to each of a plurality of circuit cards;
a first trace interconnecting the pair of first connectors and the plurality of second connectors;
a second trace connecting a first sequence of the plurality of second connectors to a first of the pair of first connectors; and
a third trace connecting a second sequence of the plurality of second connectors to a second of the pair of first connectors;
wherein a first distance from any one of the second connectors of the first sequence along the first trace to the second of the pair of first connectors is substantially equal to a second distance from the same one of the second connectors of the first sequence along the second trace to the first of the pair of first connectors; and
wherein a third distance from any of one the second connectors of the second sequence along the first trace to the first of the pair of first connectors is substantially equal to a fourth distance from the same one the second connectors of the second sequence along the third trace to the second of the pair of first connectors.

20. The backplane of claim 19, wherein the second trace is a looped trace having first and second ends connected to the first of the pair of first connectors.

21. The backplane of claim 19, wherein the third trace is a looped trace having first and second ends connected to the second of the pair of first connectors.

22. A housing comprising:
a pair of first slots adapted to receive a pair common electronic modules therein;
a plurality of second slots located between the pair of first slots, each of the plurality of second slots adapted to receive one of a plurality of circuit cards therein;
a backplane;
a pair of first connectors electrically connected to the backplane, the pair of first connectors respectively electrically connectable to the pair of common electronic modules;
a plurality of second connectors electrically connected to the backplane between the pair of first connectors, each of the plurality of second connectors respectively electrically connectable to each of the plurality of circuit cards;
a first trace disposed within or on the backplane interconnecting the pair of first connectors and the plurality of second connectors;
a second trace disposed within or on the backplane connecting a first sequence of the plurality of second connectors to a first of the pair of first connectors; and
a third trace disposed within or on the backplane connecting a second sequence of the plurality of second connectors to a second of the pair of first connectors;
wherein a first distance from any one of the second connectors of the first sequence along the first trace to the second of the pair of first connectors is substantially equal to a second distance from the same one the second connectors of the first sequence along the second trace to the first of the pair of first connectors; and
wherein a third distance from any one of the second connectors of the second sequence along the first trace to the first of the pair of first connectors is substantially equal to a fourth distance from the same one the second connectors of the second sequence along the third trace to the second of the pair of first connectors.

23. The backplane of claim 22, wherein the second trace is a looped trace having first and second ends connected to the first of the pair of first connectors.

24. The backplane of claim 22, wherein the third trace is a looped trace having first and second ends connected to the second of the pair of first connectors.

25. A method for synchronizing operation of a pair of circuit cards of an electronic module, the method comprising:
conveying a first clock signal over a first distance from a circuit card of the electronic module disposed between the pair of circuit cards to a first of the pair of circuit cards;
conveying a second clock signal over a second distance from the circuit card disposed between the pair of circuit cards to a second of the pair of circuit cards;
conveying a third clock signal over a third distance from the circuit card disposed between the pair of circuit cards to the first of the pair of circuit cards, wherein the second and third distances are substantially equal so that the phases of the second and third clock signals are substantially equal at the second and first of the pair of circuit cards, respectively; and
selecting the third clock signal at the first of the pair of circuit cards.

26. The method of claim 25, wherein conveying the third clock signal over the third distance from the circuit card disposed between the pair of circuit cards to the first of the pair of circuit cards comprises conveying the third clock signal over a looped trace disposed within or on a backplane of the electronic module, the looped trace connecting the circuit card disposed between the pair of circuit cards to the first of the pair of circuit cards.

27. The method of claim 25, wherein conveying a first clock signal over a first distance and conveying a second clock signal over a second distance comprises respectively conveying the first and second clock signals in first and second directions through a trace disposed within or on a backplane of the electronic module, the trace interconnecting the pair of circuit cards and the circuit card disposed between the pair of circuit cards.

28. The method of claim 25, further comprising receiving the first and third clock signals at an electronic circuit of the first of the pair of circuit cards.

29. The method of claim 25, wherein selecting the third clock signal at the first of the pair of circuit cards is accomplished using an electronic circuit of the first of the pair of circuit cards.

30. A method for synchronizing operation of a pair of circuit cards of an electronic module, the method comprising:
conveying a first clock signal over a first distance from a circuit card of the electronic module disposed between the pair of circuit cards to a first of the pair of circuit cards;
receiving the first clock signal at a first port of a multiplexer of the first of the pair of circuit cards;
conveying a second clock signal over a second distance from the circuit card disposed between the pair of circuit cards to a second of the pair of circuit cards;
receiving the second clock signal at functional circuitry of the second of the pair of circuit cards;
conveying a third clock signal over a third distance from the circuit card disposed between the pair of circuit cards to the first of the pair of circuit cards, wherein the second and third distances are substantially equal so that the phases of the second and third clock signals are substantially equal at the second and first of the pair of circuit cards, respectively;
receiving the third clock signal at a second port of the multiplexer of the first of the pair of circuit cards and at a controller of the first of the pair of circuit cards;
transmitting a control signal from the controller to a third port of the multiplexer upon receiving the third clock signal at the controller; and
instructing the multiplexer to transmit the third clock signal from the second port of the controller to functional circuitry of the first of the pair of circuit cards using the control signal.

31. The method of claim 30, wherein conveying the third clock signal over the third distance from the circuit card disposed between the pair of circuit cards to the first of the pair of circuit cards comprises conveying the third clock signal over a looped trace disposed within or on a backplane of the electronic module, the looped trace connecting the circuit card disposed between the pair of circuit cards to the first of the pair of circuit cards.

32. The method of claim 30, wherein conveying a first clock signal over a first distance and conveying a second clock signal over a second distance comprises respectively conveying the first and second clock signals in first and second directions through a trace disposed within or on a backplane of the electronic module, the trace interconnecting the pair of circuit cards and the circuit card disposed between the pair of circuit cards.

33. A method for selecting a clock signal at a circuit card of an electronic module comprising:
receiving the clock signal at a first port of a controller of the circuit card and at a first port of a multiplexer the circuit card;
receiving another clock signal at a second port of the multiplexer;
transmitting a control signal from a second port of the controller to a third port of the multiplexer upon receiving the clock signal at the first port of the controller; and
instructing the multiplexer to transmit the clock signal from the first port of the multiplexer to an output port of the multiplexer for output using the control signal.

34. An electronic module, comprising:
a card cage having slots for first and second common cards located at different ends of the card cage and a plurality of slots between the slots for the first and second common cards for receiving a plurality electronic circuit cards each providing a clock source within the card cage; and
a bus that connects the plurality of slots for receiving the plurality electronic circuit cards with the slots for the first and second common cards such that the bus provides a substantially equal distance to the slots for the first and second common cards from any of the plurality of slots for receiving the plurality electronic circuit cards.

35. The electronic module of claim 34, wherein second common card is a backup common card for the first common card that replaces the first common card if the first common card fails.

36. The electronic module of claim 34, wherein the bus comprises traces disposed within or on a backplane of the electronic module.

37. The electronic module of claim 34, wherein the bus comprises a looped trace disposed within or on a backplane of the electronic module interconnecting a portion of the slots for receiving the plurality electronic circuit cards and the slot for the first common card.

38. The electronic module of claim 34, wherein the bus comprises a looped trace disposed within or on a backplane of the electronic module interconnecting a portion of the slots for receiving the plurality electronic circuit cards and the slot for the second common card.
